(19) United States
(12) Patent Application Publication
(10) Pub. No.: US 2024/0123480 A1
(43) Pub. Date: Apr. 18, 2024

(54) CHEMICAL LIBERATION OF WASTE PRINTED CIRCUIT BOARDS

(71) Applicant: INTEGRATED RECYCLING TECHNOLOGIES CORPORATION, St. Cloud, MN (US)

(72) Inventors: Benjamin Turner Suslavich, Winston-Salem, NC (US); Avimanyu Das, Butte, MT (US); Courtney Alan Young, Butte, MT (US)

(21) Appl. No.: 18/277,856

(22) PCT Filed: Feb. 18, 2022
(86) PCT No.: PCT/US2022/016951

§ 371 Date: Aug. 18, 2023

Related U.S. Application Data
(60) Provisional application No. 63/150,810, filed on Feb. 18, 2021.

(51) Int. Cl. B09B 3/70; B03C 7/00; B09B 3/35; C22B 1/248; C22B 7/00; H05K 3/22

(52) U.S. Cl. CPC B09B 3/70; B03C 7/003; B09B 3/35; C22B 1/248; C22B 7/006; H05K 3/22; B09B 2101/17; H05K 2203/0783; H05K 2203/178

(57) ABSTRACT

A method of delamination of a printed circuit board includes comminuting the printed circuit board, and soaking the comminuted PCB in a solvent system comprising at least two solvents. Once soaking has been completed the method includes separating solids, and electrostatically separating different specific solids from the separated solids.

### BACKGROUND

Electronic waste (e-waste) comprising printed circuit boards (PCBs) is quickly becoming an important source of base and precious metals as recycling becomes increasingly necessary. Recycling of e-waste is a multi-billion dollar industry, and a number of U.S. states have passed laws regarding recycling of unwanted electronic, many or most of which include PCBs. PCBs present a unique challenge for metals extraction due to their high plastics content as well as the presence of brominated bisphenol epoxies and other components that can be classified as hazardous waste. In addition, much of the modern circuit board is composed of fiberglass and polymer which has little value compared to metals. Estimates on the amount of e-waste that is recycled in the U.S. alone is only about 20%. E-waste contains metal concentrations far exceeding even rich ores being mined today. Further, some of the metals in e-waste include so-called “conflict elements” such as tantalum and niobium.

PCBs are composite structures made from of a variety of materials in a layered, sandwich-like structure. FIG. 1 shows a typical multi-layer PCB 100 the type of which is common in most computers or other highly complex circuitry. The PCB 100 comprises metal layers 102 separated by insulating layers 104, with the metal layers 102 connected with through vias 106. Insulating layers comprise top composite layer 104a, bottom composite layer 104b, and substrate or prepreg layer 104c to which metal foil layers 102c, 102d (usually copper) are laminated. Further metal layers 102a and 102b are shown on top and bottom composite layers 104a and 104b respectively. There are also single-sided PCBs, and double-sided PCBs. The distinction between these classes are how many layers of electrical connection are built into the boards. Surface components on PCBs can be mounted via metallic contact pads on the surface of the board, or via through-hole mounts. Additionally, plated contact pads/fingers along the surface or edges of the board can be added to allow for connection of the circuit to an external device without solder. Often times, these non-soldered external contacts are given a gold plating to protect against corrosion and to ensure good electrical contact with the recipient contact. The plating process can be done through either “hard-gold” plating or electroless nickel immersion gold (ENIG) plating.

Hard-gold plating is the most traditional form of plating. The gold coatings are generally thicker and harder than their ENIG counterparts. Hard-gold plating is generally used on components that will see more sliding wear. Hard-gold plated contacts also include iron, cobalt and other non-noble metals which makes it difficult to wet their surface with solder which makes them unpopular for surface mounting pads. ENIG creates a much purer gold coating than hard-gold plating. However, the coating is softer and can only last so many sliding wear cycles. ENIG coatings are far easier to solder and thus are preferred for joining processes. ENIG coatings consist of two separate metallic coatings, first a nickel coating approximately 6 microns in thickness is put over the surface followed by a 0.2-micron gold layer placed over the nickel. Of course, ENIG coatings are not the most popular surface finish for boards₆₃. The HASL and newer Lead-Free HASL (Hot Air Solder Leveling) has been the industry standard due to its low cost and corrosion resistance. The HASL process involves immersing the circuit board into a molten solder bath to wet the exposed contacts with solder and then removing excess solder by blasting the surface with hot air.

To create a circuit board, a layer of prepreg 104c (fiberglass with partially cured epoxy) is attached to a layer of copper foil substrate (in FIG. 1, layers 102a 102b). A photoresist layer is added to the copper foil which is selectively cured with an image of the desired circuit. The uncured portions of the photoresist are removed, and the exposed copper is removed with acid. In double-sided and multi-layer boards, multiple individual layers are stacked and cured in an oven at appropriate temperature and pressure.

This process is known in the industry as copper-clad-laminate or CCL. Approximately 70% of circuit boards are made with an epoxy resin-based CCL process. The most popular epoxy resin CCL's are G-10, G-11, FR-4, and FR-5 but some common varieties of epoxy include Bismaleimide-Triazine (BT) modified epoxy, Polyphenylene oxide (PPO) modified epoxies, polyimide modified epoxy, and cyanate ester modified epoxies. The circuit board market primarily uses the FR-4 type epoxy for general application electronics.

Printed circuit boards typically contain roughly 26% metal, which mainly consists of copper, lead, aluminum, iron, tin, cadmium, and nickel with small amounts of gold, silver, platinum, and palladium depending on the exact design of the board, as well as the batch number. Elements like praseodymium, neodymium, rubidium, cesium, strontium, scandium, iridium, tellurium, osmium, ruthenium, gallium, bismuth, germanium, and tantalum have been identified in some surface components as well. Depending on the economic value of circuit boards, they can be colloquially classified as low, mid, high, and very high grade.

Low-grade boards are typically considered to be boards with low economic value. Generally, these boards contain no recoverable precious metals and a minimal amount of copper. Often times the boards contain few surface components of any reasonable value. Examples are old TV, VCR, and stereo boards. Mid-grade boards are similar to low-grade boards but contain multiple surface components which can contain precious metals as well as small quantities of precious metal surface coatings. Examples of mid-grade boards include mother boards, fingerless ram boards, and many low value consumer electronic devices. Upon reaching high-grade, the amount of gold and precious/conflict metals increases dramatically. While the exact distinction between mid and high grade varies based on buyers, it typically encompasses scrap hard-drive boards, RAM boards, some IC chips, tantalum capacitors, some telecommunication boards, modern CPU and ball grid array (BGA) chips, etc. As electronics miniaturize, the amount of precious metals contained in boards is ever decreasing. The final grade is very high-grade boards. Boards in this classification are becoming increasingly rare and often times the collector value of the boards is higher than the material value. There are some more modern boards used for telecommunications equipment which might fall into the very high-grade classification, as well as pre-processed boards such as ram fingers, and CPU legs. CPUs from the 1980s and 1990s are often revered as the “gold-standard” for vintage circuit board recovery. Some BGA chips also contain large amounts of platinum. Very high-grade scrap is popular with small garage-scale e-waste recyclers since the total process volume is small However, almost all of the high-grade materials are no longer manufactured and thus are, in essence, a non-renewable man-made resource.

There are currently several known methods for extracting and recovering valuable metals from printed circuit boards (PCB's) and other types of electronic waste. These known methods include hydrometallurgical and pyrometallurgical techniques used to extract the metals from the e-waste. But these known methods are inefficient and costly. In addition, these methods generate tremendous amounts of toxic waste water.

The pyrometallurgical approach is based largely on smelting, which involves using heat to incinerate and subsequently melt, and from there, selectively oxidize the metals contained in the PCBs. Pyrometallurginal recovery is popular since a large variety of e-waste can be accepted into a furnace. The process is efficient and, if done properly, at a low environmental impact. One of the primary concerns of the pyrometallurgical route is the presence of halogenated flame retardants such as tetrabromobisphenol-A. In a smelter, these compounds can lead to the formations of dioxins as well as halogenated discharge gases unless special procedures and filters are in place. In addition, the facilities for efficient smelting are exorbitantly expensive to build. Without proper (and expensive) containment systems, incineration of electronic waste can release dioxins, furans, polybrominated organics, and polycyclic aromatics produced which can cause detrimental health and environmental problems. On a small scale, home smelters may be used to process PCBs, but they lack all or nearly all of the environmental safeguards of established smelters.

The basic hydrometallurgical approach uses chemicals in the aqueous phase to solubilize and/or dissolve metals. This process is called leaching and can be facilitated by various reagents, which can be categorized based on their composition and mechanism of action. Acid leaching, basic oxidizing leaching, acid oxidizing leaching, and bioleaching, as well as leaching using I₂ with inorganic acids are all feasible. One of the large challenges of the hydrometallurgical process is liberation (or at least achieving enough surface exposure) of the PCB feed as well as controlling the feed composition which is controlled by physical processing. In most PCBs, the base metals are encased in an inert polymer shell which guards against leaching. For effective leaching, the material to be leached must have direct contact with the active chemical. Increasing the exposed area increases the kinetics of leaching and thus make the material more amenable to the hydrometallurgical process. The problem is that PCBs in their natural state have extremely low exposed surface areas. In addition, due to the presence of polymers in untreated PCBs, the natural PCB is refractory, which means, in the metallurgical sense, it is not easily amenable to cyanide leaching for the recovery of gold. Other leaching techniques may be effective at recovering surface gold, palladium, and platinum. One such method utilizes an oxidative leaching method such as perchlorate leaching followed by extraction using an organic solvent and a complexing agent. An important point to take away is that all hydrometallurgical processes, as well as some pyrometallurgical processes, require a certain degree of physical processing in order to be feasible. They dissolve the metals in solution, and thus create a large amount of waste toxic byproduct, that must be properly treated, adding expense to the process.

### SUMMARY

In one embodiment, a method of delamination of a printed circuit board includes comminuting the printed circuit board, and soaking the comminuted PCB in a solvent system comprising at least two solvents. Once soaking has been completed the method includes separating solids, and electrostatically separating different specific solids from the separated solids.

In other aspects, soaking in a solvent system includes soaking in a system of reagents comprising two swelling agents. The at least two swelling agents in one embodiment are n-methyl-2-pyrrolidone (NMP) and resorcinol. The at least two swelling agents in another embodiment are ethylene glycol and salicylic acid. The solvent system further includes a diluent in one embodiment. The solvent system is in various embodiments agitated, heated to a temperature of about 110° C. to about 210° C., or both. Electrostatically separating is preceded by rinsing and drying. In one embodiment, the at least two solvents comprise solvents having a combined high interaction parameter between the solvent system and polymers of the PCB. The solvents may be chosen based on a predicted normalized interaction with polymers of the PCBs. Separating solids includes density separation in one embodiment.

In another embodiment, a method of delaminating a printed circuit board (PCB) includes shredding the PCB, swelling the shredded PCB with a swelling agent bath comprising at least two swelling agents, and agitating to assist in delaminating the swelled shredded PCB.

In other aspects, a diluent is provided to the swelling agent bath to stabilize the swelling agent bath for temperature. The swelling agents may be chosen based on a predicted normalized interaction with polymers of the PCB. The at least two swelling agents include in one embodiment n-methyl-2-pyrrolidone (NMP) and resorcinol. A diluent is provided to the swelling agent bath in one embodiment. The swelling agent bath is agitated in one embodiment.

In another embodiment, a method of recovering components of a printed circuit board (PCB) includes shredding the PCB, and delaminating the PCB with a solvent system. Delaminating includes soaking in the solvent composition bath comprising a swelling agent and a diluent, wherein the swelling agent is a combination of at least two reagents.

In other aspects, the solvent system is used at a temperature of about 110° C. to about 210° C. The solvent system swelling agents comprise n-methyl-2-pyrrolidone (NMP) and resorcinol, in a by mass ratio of NMP to resorcinol of at least 8:1.

### BRIEF DESCRIPTION OF THE DRAWINGS

FIG. 1 is a perspective view of a typical PCB on which embodiments of the present disclosure may be practiced;

FIG. 2 is a flow chart of a method according to an embodiment of the present disclosure;

FIG. 3 is a flow chart of a method according to another embodiment of the present disclosure;

FIG. 4 is a more detailed flowchart of a portion of the method of FIG. 3;

FIG. 5 is a flow chart of a method according to another embodiment of the present disclosure;

FIG. 6 is a more detailed flowchart of a portion of the method of FIG. 5;

FIG. 7 is a diagram of a polymer/solvent interaction;

FIG. 8 is a general diagram showing stages of polymer swelling;

FIG. 9 is a graph of a response surface of the percent of the product mass which reported to concentrate versus temperature and interaction parameter;

FIG. 9 is a graph of a response surface of a percent of product mass which reported to concentrate versus temperature and interaction parameter;

FIG. 10 is a graph of a response surface of a percent of product mass which reported to concentrate versus time and interaction parameter;

FIGS. 11 and 12 are graphs of response of yield and grade for an ethylene glycol/salicylic acid solvent system of the present disclosure;

FIGS. 13 and 14 are views of polymer swelling in PCBs treated with embodiments of the present disclosure;

FIGS. 15 and 16 are graphs showing swelling versus time and mass change versus time respectively for NMP/resorcinol embodiments of the present disclosure;

FIG. 17 is a graph of a linear region of the graph of FIG. 16 plotting the square root of time (t) and the reciprocal of the sample thickness (h);

FIG. 18 is a graph showing mass change versus time for an ethylene glycol/salicylic acid embodiment of the present disclosure;

FIG. 19 is a graph of a linear region of the graph of FIG. 18 plotting the square root of time (t) and the reciprocal of the sample thickness (h);

FIG. 20 is a view of a section of PCB after treatment in NMP/resorcinol according to an embodiment of the present disclosure;

FIG. 21 is a graph showing penetration depth versus solvent temperature into a PCB subjected to an embodiment of the present disclosure;

FIG. 22 is a graph of yield and grade over multiple replicated tests of a solvent system according to an embodiment of the disclosure; and

FIG. 23 is a graph showing percentage of particle diameter passing for various elements of delaminated PCBs according to an embodiment of the present disclosure.

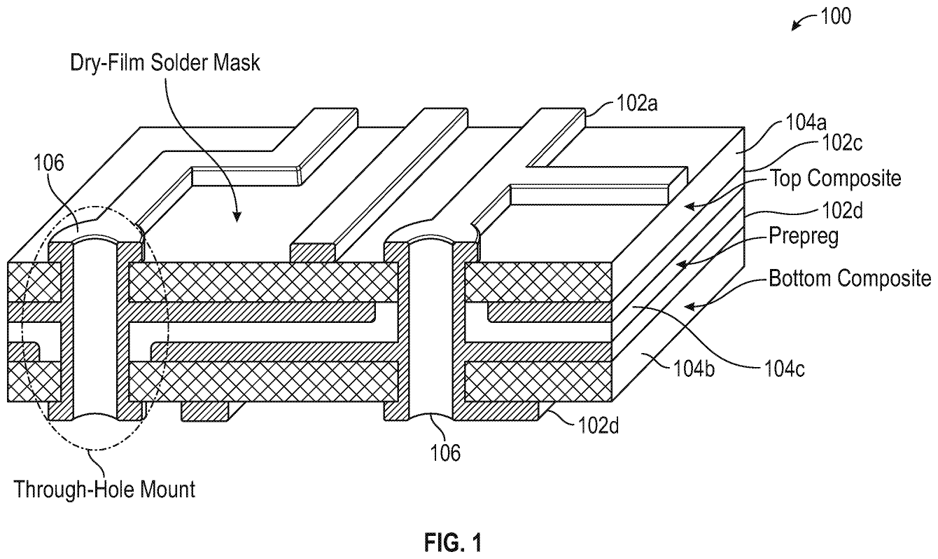

### DETAILED DESCRIPTION

Embodiments of the present disclosure provide methods of recovering valuable metals from PCBs using a solvent system, including multiple swelling agents, that delaminate the PCBs instead of dissolving included metals and other components of the PCBs. The solvent system is effective at separating the valuable metals from the fiberglass and epoxy that make up most of what is in a PCB. The “solvent swelling” of the present disclosure also creates less toxic waste than conventional hydrometallurgical and pyrometallurgical methods, and is both more efficient than known technologies and creates less toxic waste. The examples provided below are used on FR-4 epoxy type PCBs, which are the most common. The solvents (e.g., swelling agents) described herein are suitable for use with delamination of FR-4 epoxy type PCBs. Other solvents may be more or less suitable for other types of PCBs, but choice of a solvent system is based on the interactions between the solvents and the materials to be swelled in the various processes, without departing from the scope of the present disclosure.

In one embodiment, two types of chemicals are used. The first one is a swelling agent which can be a solid or liquid which is used to penetrate the PCBs. There are numerous acceptable swelling agents, and embodiments of the present disclosure use two or more such swelling agents, including, but not limited to, n-methyl-2-pyrrolidone (NMP); resorcinol; Trifluoroacetic acid; 2,3,4,5 Tetraflurophenol; and 2,3,5 Triflurophenol. The second agent, which is a diluent, is a liquid and has several functions. These include: increasing the effectiveness of the swelling agents; providing for easy filtering of the product if the swelling agent is a solid or semi-solid at room temperature; and reducing the cost of achieving a required volume of reagent mixture

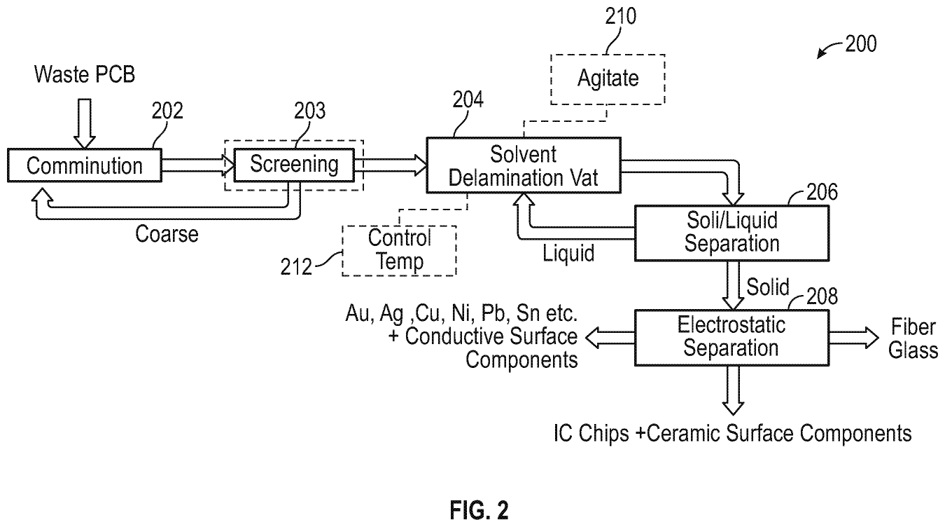

A method 200 according to an embodiment of the disclosure is shown in flow chart form in FIG. 2. Method 200 of delaminating a printed circuit board (PCB) comprises comminuting the printed circuit board in block 202, soaking the comminuted PCB in a solvent delamination vat containing a solvent system comprising at least two solvents in block 204, separating solids from the liquid in block 206, and electrostatically separating different specific solids from the separated solids in block 208. Soaking in a solvent system as in block 204 comprises in one embodiment soaking in a system of reagents that contribute to swelling of the comminuted PCB during the soaking. In one embodiment, the system of reagents is a mixture of at least two swelling agents. One example of a mixture of two swelling agents is a mixture of NMP and resorcinol. In one embodiment, the solvent system further comprises a diluent. The solvent system may be agitated during soaking in one embodiment, as indicated at optional block 210. Also, in optional block 203, the comminuted PCB is screened for coarse pieces to be further comminuted at block 202 until a predetermined piece size passes to the solvent delamination vat.

In one embodiment, temperature is controlled during the soaking, as shown at optional block 212. A temperature for soaking is in one embodiment between about 110° C. to about 210° C. This temperature encourages the delamination process without breaking down the swelling agents.

Following delamination, in one embodiment, the solids are separated from the liquid in block 206 by density separation, in which heavier components sink. In one density separation embodiment, layers of higher density and lower density liquid may be used for further density separation, as is known in the art. In one embodiment, the delaminated components are separated electrostatically in block 208 after a rinsing and drying operation. Rinsing and drying may be performed as is known in the art to facilitate electrostatic separation.

In one embodiment, the at least two solvents comprise solvents having a combined high interaction parameter between the solvent system and polymers of the PCB. This encourages delamination. In one embodiment, the solvents are chosen based on a predicted normalized interaction with polymers of the PCBs.

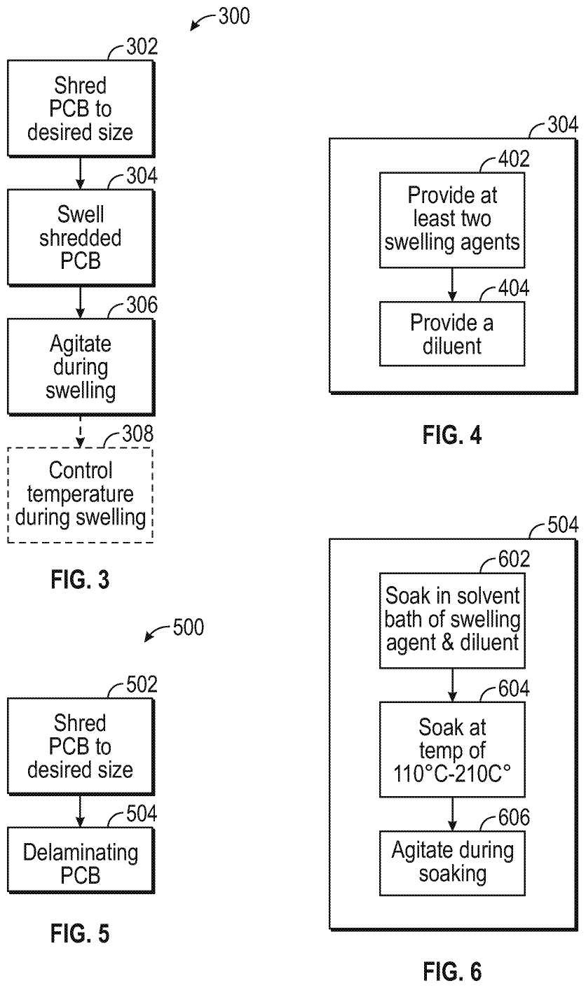

Another method of delaminating a PCB is shown in flow chart form in FIG. 3. Method comprises in one embodiment, shredding the PCB in block 302, in one embodiment to a desired, predetermined size, swelling the shredded PCB with a swelling agent bath comprising at least two swelling agents in block 304, and agitating to assist in delaminating the swelled shredded PCB in block 306. The swelling agent bath is agitated as in block 306 to encourage delamination. In one embodiment, temperature is controlled during swelling at block 308.

In one embodiment, the swelling block 304 of method 300 further comprises, in addition to providing at least two swelling agents at block 402, providing a diluent to the swelling agent bath at block 404. Addition of a diluent, such as water, is used for various purposes, including to stabilize the swelling agent bath for temperature. The at least two swelling agents are in one embodiment n-methyl-2-pyrrolidone (NMP) and resorcinol. In another embodiment, the two swelling agents are ethylene glycol and salicylic acid. Ratios of the swelling agents by mass are in one embodiment at least 8 NMP to 1 resorcinol, and at least 3 ethylene glycol to 1 salicylic acid. The swelling agents are chosen in one embodiment based on a predicted normalized interaction with polymers of the PCB.

As shown in FIG. 4, a diluent may be used with the swelling agents. The diluent is used for various purposes. When the diluent, a third chemical species in the solvent system, is added, the reagent-reagent self-interaction is balanced by the reagent-diluent interaction. By virtue of being soluble, the reagent-diluent interaction, to be effective, is larger than the reagent-reagent interaction. Otherwise, the reagent would not be soluble in the diluent.

The effects of adding a diluent to the solvent system serves several purposes. First, the diluent can serve as a solvent for the active reagent. Essentially, when using an active reagent (the solvent which penetrates the polymer) that is not a liquid at room temperature, the addition of a second solvent can help dissolve the active reagent allowing for more convenient processing. Second, the diluent can likely prevent polymers from dissolving back into the solvent. Third, the diluent acts as an energy transfer medium when using solid active reagents with agitation. Fourth, the diluent can reduce the cost of the solvent system if either an expensive active reagent is used, or if a cheap diluent is selected. Fifth, the diluent can act as a temperature regulator to prevent excessive heat which is especially important with active reagents which are temperature sensitive. A diluent may be chosen for its high boiling point and temperature stability even with high concentrations of active reagent dissolved at the operating temperature.

In another embodiment, a method 500 of recovering components of a printed circuit board (PCB) is shown in flow chart form in FIG. 5. Method comprises shredding the PCB in block 502, in one embodiment to a desired, predetermined size, and delaminating the PCB with a solvent system in block 504. Delaminating in block 504 is shown in greater detail in FIG. 6. As shown in FIG. 6, block 504 further comprises in one embodiment soaking in the solvent composition bath comprising a swelling agent and a diluent in block 602, wherein the swelling agent is a combination of at least two reagents. The delamination process may be operated by keeping its temperature at about 110° C. to about 210° C. in block 604. Depending on the reagents and diluent chosen, this temperature range may vary In one embodiment, the solvent system swelling agents comprise n-methyl-2-pyrrolidone (NMP) and resorcinol, in a by mass ratio of NMP to resorcinol of at least 8:1. Agitation may also be applied in block 606 during soaking. Agitation at a predetermined constant or near constant RPM is performed in one embodiment.

Solvents used in the embodiments of the present disclosure, when solid at operating temperatures, are dissolved into a solvent system with a diluent. This allows for the use of nontraditional solvents, that is, those that are not liquid at operating temperatures and pressures. In a binary (or more) solvent system of the present disclosure, the less the active reagent (the solid) is soluble in the diluent (liquid) at room temperature, the more effective the system is. Further, multi solvent system outperform single solvent systems by a significant margin in delamination of PCBs.

Factors that affect delamination of PCBs, discussed generally above, are discussed further with respect to testing, which is also described further below.

Delamination of the metals from the polymers and resins of the PCBs in the various embodiments does so without dissolving the elements into solution, despite the use of a solvent system bath. Instead, the solvents swell the PCBs to expand, or swell, the polymers to allow the metal foils to be released, or delaminated, from the polymers.

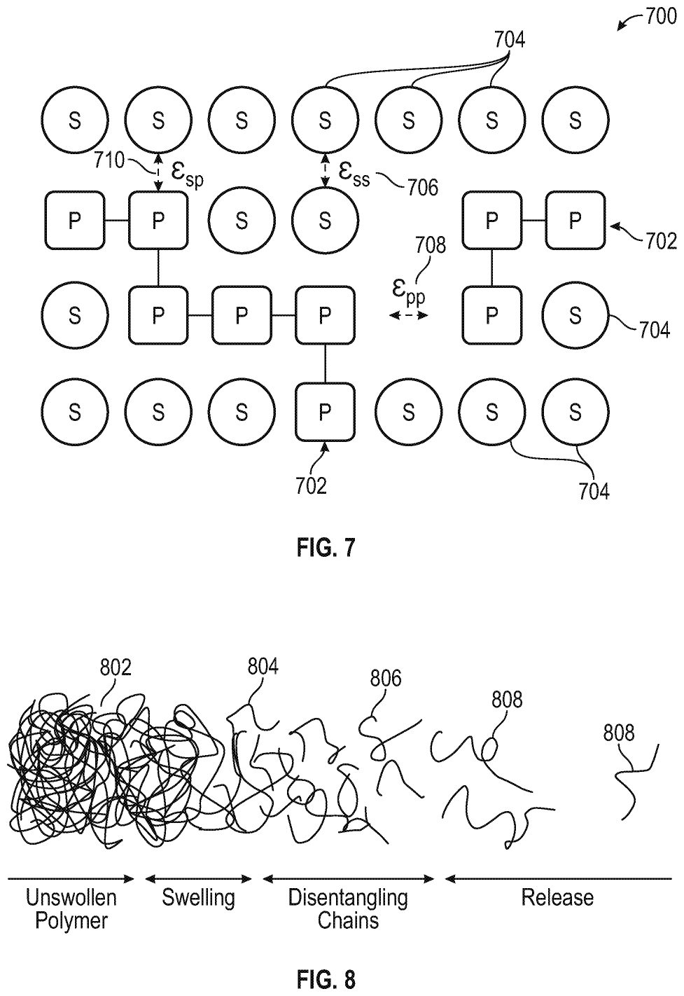

FIG. 7 shows a basic diagram of interaction between a polymer and a solvent. Polymer chains 702 and solvent molecules 704 are shown as the solvent molecules are in the process of swelling (e.g., being taken up by) the polymer. Within this system, there are independent solvent molecules and polymer chains consisting of monomer units. To simplify this model, only the immediately adjacent sites are considered for possible interactions. As shown in FIG. 7, there are three distinct interactions for a chemical system with two components. There is the solvent-solvent interaction (εₛₛ) 706, polymer-polymer interaction (εₚₚ) 708, and the solvent-polymer or polymer-solvent (they are the same) interaction (εₛₚ) 710. The overall system energy is the sum of the energies of each element which interacts in the system which is shown in Equation 1 below where Npp is the number of polymer segments (monomer units) which interact with other polymer segments, Nps is the number of polymer segments which interact with solvent molecules, and Nss is the number of solvent molecules which interact with other solvent molecules.

Eₘᵢₓ=<Nₚₚ>εₚₚ+<Nₚₛ>εₚₛ+<Nₛₛ>εₛₛ (1)

The number of available sites is proportional to volume fraction of the segment or molecule in the system. The average number of available sites for a solvent molecule is represented by (Z) and is referred to as the lattice coordination number. the Flory-Huggins interaction parameter (χ) is defined in the following expression:

$$X = - ( \frac{z}{2} ) \frac{( {ε}_{pp} + {ε}_{ss} - 2 {ε}_{ps} )}{kT} \qquad ( 2 )$$

To maximize the parameter, εₚₛ should be as large as possible and the self-interaction of the polymer to itself and the solvent to itself should be minimized. The derivation is beyond the scope of this disclosure and is not needed for understanding. What is to be understood is that the change in the chemical potential of the system is proportional to the volume fraction of the solvent (ϕ₁), the volume fraction of the polymer (ϕ₂), and the interaction parameter (χ). It is also inversely proportional to x, which is the ratio of the molar weight of the polymer to the molar weight of the solvent (MWt polymer/MWt solvent) as shown by the following expression in Equation 3:

$${Δμ}_{s} = RT ( ln ( {ϕ}_{1} ) + {ϕ}_{2} ( 1 - \frac{1}{x} ) + {χϕ}_{2}^{2} ) \qquad ( 3 )$$

Examining the terms, as the molecular weight of the polymer increases the 1/x term approaches zero. This increases the value of the overall expression and thus decrease the overall solubility. In addition, increasing the molecular weight of the solvent should help as well; however, there are more constrictions on the molecular weight of the solvent than there are for a polymer.

Further exploration of the Flory-Huggins equation requires a basic understanding of the behavior of polymers in solutions. Polymer dissolution occurs in several unique steps as illustrated by FIG. 8. The first stage involves swelling of the polymer. When small molecules enter the matrix, they occupy a set volume within the matrix. This volume limits the spatial regions which the polymer chains can occupy. As this process continues, more and more molecules enter the polymer matrix and occupy more volume. The system has two choices once all of the free volume is used up: first, it could preclude further intake of small molecules and the system would remain at this state in equilibrium; or, the second, is the bulk system can expand to provide more volume. This second option occurs when the polymer-solvent interaction parameter is large. This process is also called gelling.

Polymer swelling is shown in broad form in FIG. 8. Unswollen polymer is tightly packed as shown at 802. As the solvent system works its way into the polymers, swelling occurs as shown at 804. Chains of the polymer disentangle at 806, and fully release at 808. While all steps of this process are not necessary in the embodiments of the present disclosure, the swelling action of solvents into the polymer, along with heating and agitation, facilitate the delamination of the metals foils from the polymer substrates.

For many systems, this process stops at the swelling stage. Some polymers, especially thermosets or other polymers with a highly entangled or crosslinked structure, cannot move to the disentangling stage since the polymer has such a large degree of steric or chemical attachment to the bulk system. In other systems, the process can continue to the disentangling stage where, through random motion, the chains can begin to unwind. This process is much faster for shorter chains than it is for longer chains. The final stage of the process is complete release which occurs when the chains are completely disentangled from the polymer matrix and can freely exist in the fluid phase.

With the foregoing in mind, a feature of polymer systems is that solvents with large interaction parameters to the target polymer are generally very poor at dissolving the polymer into the solvent solution and generally promote a high degree of swelling in the target polymer. This is not a fact which is completely intuitive, especially when considering the molecules with large interaction parameters to the target polymer are generally excellent at swelling the polymer. To state this fact another way, molecules which produce high swelling in polymers generally are poor solvents for the polymer₄₆. Exploring Equation 3 further, notice that the volume fraction of polymer (ϕ₂) decreases as the polymer swells which helps decrease the chemical potential. This is coupled with an increase in the volume fraction of solvent; however, it is the polymer which has most of the control of the process. In addition, χ can vary with the concentration of the polymer. This relationship can be directly or inversely related and its magnitude can vary greatly. Some systems do not experience much change in interaction parameter value with change in polymer concentration, while some systems increase greatly and some systems decrease greatly.

Looking at Equation 2, it can also be seen that the interaction parameter is inversely related to temperature. This is completely intuitive since higher temperatures can diminish the enthalpic effects which drive the system and increased thermal motion decrease the strength of the interactions. However, this does not mean that cold temperatures increase swelling. Often, high temperatures are needed to ensure that there is enough free volume within the polymer itself and to allow for a softer state in the polymer where the strands can move freely as swelling occurs. This is an example of an inverted-U type system where increasing temperature can not only result in diminishing returns, but can be counterproductive when it comes to polymer swelling₄₇.

For use with the embodiments of the present disclosure, these interactions and functions indicate, and are usable for determining details of the methods. First, despite a polymer having poor solubility in a solvent, the solvent can still have excellent solubility in the polymer. Just because a polymer is insoluble in a solvent does not make it inert to that solvent. Second, the polymer-solvent system can be in a very delicate balance especially if the interaction parameter is close to a critical value. Near this critical interaction value, small changes in the solvent formulation or the molecular weight of the polymer can cause a dramatic decrease in solubility. A polymer can have poor “solubility” in a solute but can experience excellent swelling. One reasonable distinction which can be made is large amounts of swelling are indicative of a large solubility of the “solvent” (which is acting as a solute) inside the polymer which is acting as the solvent.

In this application, the term “solvent system” will be used to describe the reagent or collection of reagents used to bring about delamination of PCBs either through a swelling process, a solvation process, or a combination of both. However, the solvent system, while excelling at delamination, may by quite poor as a “solvent.” Using this knowledge of interactions, systems may be created to produce a large degree of swelling in PCBs, but without leaching a large amount of polymer into the liquid phase.

Atoms can form several different kinds of bonds depending on the nature of the atomic bonding. These bonds are classified as either ionic, covalent, metallic, and dative. There are many ways to actually predict bonding such as molecular orbital theory, valance bond theory, etc. Each theory has its own strengths and weaknesses, but there is one very fundamental theory which is both intuitive and encompasses many real systems. The theory is known has Hard/Soft Acid-Base theory, or HSAB for short. HSAB operates with the following principle: hard acids like to bond to hard bases and soft acids like to bond to soft bases. Hard atoms are usually small, highly charged, with highly constrained atomic orbitals; whereas, soft atoms are usually larger, with more dispersed atomic orbitals, with lower charge states. For example, the Fe(III) ion is a hard acid, whereas the S-ion is a soft base.

As techniques developed, the present state of knowledge has led to a state in which electronic structure predictions are commonplace in mainstream science. Today, the electron structure of even medium-sized molecules can be performed with surprising accuracy even on tablet computers. Accordingly, a history of density function theory is not necessary for an understanding of the tools used today

A numeric descriptor of the hardness/softness of an atom or even an atom in a molecule may be determined using the Fukui functional to predict local and absolute hardness in a molecule with one or more atoms. However, to discuss the Fukui functional, there needs to be a brief and grossly oversimplified introduction to density functional theory (DFT)

Most atoms, and, for that matter, molecules, have multiple electrons. Each electron contains characteristic information found in its wave function. Each electron has a spatial position given by three coordinates (XYZ) as well as a spin component. Thus, each electron has four coordinates to account for. Now, to calculate the energy of the electron, all that needs to be done is simply add the following three energy terms (this is known as the Hamiltonian): the kinetic energy term, a nuclear attraction term, and an electron-electron interaction term. The first two are straightforward only depending on the electron's mass, radial distance, and nuclear charge. However, once multiple electrons are added, the interaction terms become a three-body (or greater) problem and an approximation (as well as a supercomputer) is needed to solve it. Fortunately, given advancements in understanding and techniques, today, the electron structure of even medium-sized molecules can be performed with surprising accuracy even on tablet computers.

In short, molecules can be “non-bonding” bond donors, or they can be acceptors. This fact differentiates it from HSAB. Thus, a molecule can have many highly electrophilic hydrogens and may be a prime candidate for hydrogen bonding; however, unless the recipient molecule has enough hydrogen bond acceptors, the interaction between the molecules will be poor. Interaction is a two-way street and strong interactions only occur when both molecules have the electronic structure to interact. Moreover, in order to achieve strong interaction, the mechanism of the interaction must be similar as well (e.g. a molecule with strong hydrogen bonding will not be as ready to interact with a molecule without strong hydrogen bonding but with large amounts of dispersion forces).

Examples of the methodology for testing the methods of the present disclosure are performed in part using Conductor Screening Model—Realistic Solvation (COSMO-RS). COSMO theory utilizes the electronic structure to semi-quantitatively determine the non-bonding interactions from a structural input alone. What makes COSMO-RS attractive is that the entire process from the DFT calculation to the thermodynamic calculations to predict solubility based on the change in chemical potential has been aggregated and streamlined in user-friendly GUI based programs such as COSMOtherm. The examples discussed herein utilized COSMOtherm for all predictions. The parametrizations and the exact nature of the calculation can be found in a later section.

In screening tests performed using the methods described herein, the solubility of a number of solvents in a pure solvent system was calculated using COSMOtherm. The value which the solvents were ranked by was their Log(X sol) value. This value is related to the interaction parameter. The calculation is solved iteratively, starting with an infinite dilution of the solute, and increasing the concentration until convergence is reached. By default, COSMOtherm first computes the chemical potentials (μⱼ^{(P)}) for all pure compounds j. Next, the chemical potentials of the compounds (at infinite dilution) in water are calculated (μⱼ^{(∞)}). If the screened compound is a solid (such as the case with a polymer), the Gibbs free energy of fusion (ΔG_{f}_{ᵤₛ}) is used. This value can be approximated for polymers if it is not known, as will be discussed in a future section. Obviously, since the value is an approximation, it is a major source of error in the absolute value of the solubility. This is one of the many reasons why the absolute value is not reliable for the solvent screening data. However, the relative values are accurate when looked at holistically. The initial steps of the calculation are shown in Equation 4:

$${Log}_{10} ( {x}_{j}^{SOL ( 0 )} ) = \frac{[ {μ}_{j}^{( P )} - {μ}_{j}^{( ∞ )} - max ( 0 , Δ {G}_{fus} ) ]}{( RT ln ( 10 ) )} \qquad ( 4 )$$

$${Log}_{10} ( {x}_{j}^{SOL ( 1 )} ) = \frac{[ {μ}_{j}^{( P )} - {μ}_{j}^{( ∞ )} ( {x}_{j}^{SOL ( 0 )} ) - max ( 0 , Δ {G}_{fus} ) ]}{( RT ln ( 10 ) )} \qquad ( 5 )$$

The result of Equation 4 is only valid if the concentration of the solute is extremely low, but if the results are further refined iteratively by substituting the results of Equation 4 (xⱼ^{SOL(0)}) into Equation 5, a far better approximation is achieved. When the values of xⱼ^{SOL(η and η-1)} converge, the calculation is finished.

Further details of methods and the science behind the methods are provided below.

Screening tests were performed to test factors that affect delamination of PCBs. Those factors included time, temperature, interaction, and agitation to see the effect they had on the amount of “heavy” product which would sink in heavy media separation. solvents chosen were ranked based on their predicted normalized interaction with the polymer. The normalized interaction was calculated from the relative screening Log(Xsol) value generated by COSMOtherm. The Log(Xsol) was divided by the Log(Xsol) value of Dimethyl Sulfoxide (DMSO). This was done so that the interaction values could be easily compared to one another. Dimethyl Sulfoxide was chosen because it is a functioning solvent with middle-of-the-road effectiveness. The normalized interaction is also referred to in this report as the interaction parameter (X).

### Explanation of Variables

Variables were chosen based on their predicted influence on the delamination process. Time and temperature were chosen for kinetic considerations. Delamination processes take place on timescales of roughly one hour to several days. Shorter times are preferred to reduce industrial implementation issues. It was predicted that higher temperatures would increase the kinetics of the methods.

### Solvents

Single solvent tests were performed to have a baseline for further testing of the methods. Three solvents were used individually: Cyrene, dimethylformamide, and 3-fluorophenol which have normalized interaction parameters of roughly 0.69, 1.08, and 2.00, respectively. All three solvents are liquids with roughly equivalent molecular weights as well as boiling points.

### Experimental Procedures

The determination of mass yield with varying parameters such as reagent choice, time, percent solids, and temperature was undertaken following the delamination tests. The typical procedure was as follows. Twenty grams of shredded printed circuit board from waste hard drives was measured. The samples were taken with a modified “grab” method utilizing a beaker with a volume roughly equal to the desired sample size which was pushed into the sample tray similar to a core sample. The untreated sample is called the feed board. The feed board was sieved on a RoTap and each size fraction was massed and then recombined to form the feed. Prior screening gives valuable particle size information which not only helps verify the representativeness of the taken sample compared to prior samples, but also gives each test a starting point to track each particle size class as it delaminates in the reactor. No attempt was made to clean the feed or remove any detritus particles such as sticker fragments and bits of shredded foam. The intention behind this choice was to try to minimize any misleading results which would not be robust enough for practical applications. Presuming that this process could be used with minimal preprocessing on the boards. For these tests, the only preprocessing to the boards is the shredding using a polymer shredder.

Shredded PCBs (feed board) were then added to a 250 mL round bottom flask equipped with reflux condenser and thermometer. The flask contained the appropriate quantity of solvent reagent to achieve the target percent solids (by mass) for the test and was, in addition, preheated to the temperature required for the experiment. Preheating of the solvent was done to minimize warmup time which could yield false conclusions for low time periods of the test. The reaction temperature was maintained using an oil bath.

After the reaction was completed, aliquots of the liquid were taken for analysis. The reaction mixture was hot-filtered using a vacuum funnel and the products were washed with methanol followed by acetone to remove any residual solvent and to facilitate fast drying. Methanol and acetone were determined prior to the experiment not to induce further swelling to circuit boards at standard pressures and temperatures where these solvents are in their liquid phase. After drying the filtrate, the treated boards were placed in an oven set to roughly 80° C. overnight to remove any residual volatile species which might interfere with density separation.

Density separation was performed using a lithium meta-tungstate (LMT) solution. The density of the first solution was 2.74 g/cm3. The delaminated printed circuit boards were placed in the high-density LMT solution and agitated by hand to ensure the wetting of the entire surface of the boards. The delaminated printed circuits boards separated into two fractions—float and sink. The sinking fraction was designated as ‘Con’ and the float fraction was filtered off and introduced to the second LMT solution at a density of 1.86 g/cm3. After further stratification, the floating fraction was designated as ‘Tails’ and the sinking fraction “Mids’. After filtering and washing of all three factions to recover the remaining LMT, the three density fractions were dried overnight at 80° C. The three density classes were then sieved on a RoTap and each size class was collected and massed. The mass data represents the total mass yield of the process.

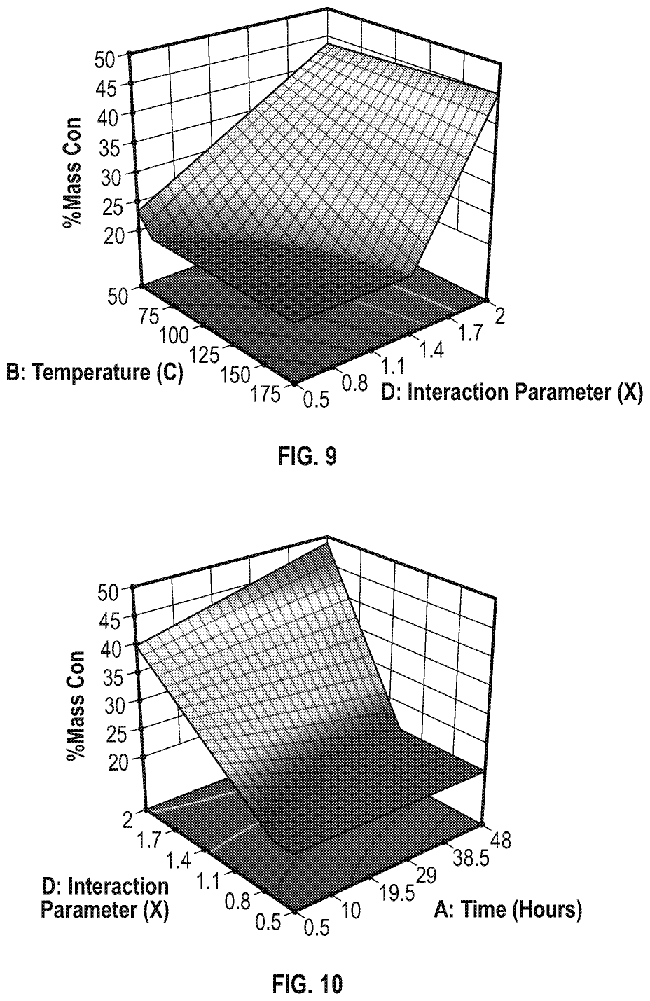

The graphs shown in FIGS. 9 and 10 depict the response surface of the percent of the product mass which reported to the Con. Because untreated boards in this experiment produced roughly 20% con, the models are truncated to prevent misleading results.

From FIGS. 9 and 10, it can be seen that the primary factor which influences the percent of the mass reporting to the con, which will be referred to as yield henceforth, was the value of the normalized interaction parameter. The normalized interaction parameter was calculated from the Log(Xsol) value predicted by COSMOtherm. The Log(Xsol) of the chosen solvent was divided by the Log(Xsol) value of dimethyl sulfoxide.

The graphs show that the interaction parameter has the strongest influence on the yield of the sample. That is to say, the most significant factor in determining the mass of con which is liberated enough to ensure sinking in the LMT separation is largely determined by the chemical nature of the solvent. Time is also directly correlated to liberation; however, in FIG. 10, it appears that the inverse is true for solvents with a normalized interaction parameter below 1. This is due to the decomposition of the solvent Cyrene at elevated temperatures causing large experimental error and in one case, complete deletion from the model. It is for this reason that the confidence in the model is less for smaller interaction parameter values. However, analysis of variance (ANOVA) shows that the remainder of the model is still good. Thus, the values with interaction parameters of 1 and above are fairly accurate.

It is seen that increasing the interaction parameter and increasing the temperature of the reactor increases the yield. It can tentatively be held that the yield increase is due to an increase of delamination of the boards. That is to say, laminated boards will generally float, and delaminated copper sheets will sink.

The response surfaces indicates several things. First, the chemical structure of the solvent plays an important role in the delamination process. Therefore, reagent selection appears to be the most telling parameter in the disclosed methods. Second, the relative predicted Log(Xsol) generated by COSMOtherm appears accurate for the screened chemical species. Third, time appears to be secondary to the interaction parameter. This makes sense since the delamination process is most likely to be kinetically controlled by diffusion and thus, longer times allow for the delamination of larger particles. Finally, the temperature seems to be of lesser importance from these results. However, due to problems with decomposition in the original tests, it is not completely clear as to the magnitude of the effect temperature has.

None of the reagents tested in these initial screening were used in refined tests, due to several factors. Cyrene decomposes even at moderate temperatures making it undesirable for any process in which longevity of the solvent is desirable. Dimethylformamide, while not suffering from decomposition as Cyrene, does present some health hazards. The other reagent, 3-fluorophenol, showed good power as a solvent. Further, all isomers of mono, di, tri, quatra, and penta fluorophenols appear to be effective in delaminating PCBs. However, use of fluorinated compounds on the industrial scale is not feasible due to possible additional regulation or permitting requirements under RCRA and the Clean Air Act, especially considering that reagents of similar effectiveness that are non-halogenated are readily available.

Therefore, reagent choice using COSMO-RS can be used to predict reagents which might be more suitable for the task of delamination. Secondly, increasing temperature does increase the yield of Con produced. Finally, the process is dependent on the time for which the boards remain in the solution. Because this process is likely controlled by diffusion, time and particle size are related.

### Agitation Tests

Delamination of PCBs can be hindered by mechanical fasteners which can penetrate multiple layers of the board. These fasteners can be from electrical connections (thorough vias and the like) in multi-layer printed circuit boards, or from feedthroughs for surface-mounted components. Regardless of their original purpose, they can cause problems in the delamination process because they counteract delamination. To solve the problem, the fasteners are broken or the material that the fastener sandwiches together should be removed. These fasteners, because of their similarity to the steel pins used to bind multiple layers of steel together, will be referred to as ‘rivets’ henceforth.

Removal of the material between layers may be accomplished through a two-step process. First, the polymer binder is removed or weakened so the particles/fibers within the composite become independent for easy separation. Second, the particles/fibers are transported out of the area. Transport is difficult in a stagnant system because the only viable mechanism for transport would be through volumetric expansion of the polymer matrix. Due to the high degree of crosslinking in thermoset polymers, epoxies do not exhibit large degrees of swelling and thus are not ideal for transporting material though volumetric expansion type mechanisms. However, expansion could be aided through solid-solid forces, solid-liquid forces, or inertial forces generated by agitation.

In these tests, an overhead mixer was used to create a stirred tank reactor (STR). STRs can generate large shear forces which are likely ideal for this application. Furthermore, STRs are easily worked within lab applications and can be scaled up to the industrial level. While, the specifics of any scale-up can be predicted, the exercise becomes less accurate when considering non-homogeneous, slurries of high percent (high aspect ratio) solids with varied composition depending on the equipment used to create the feedstock.

### Sampling

PCBs taken from hard drives were used in this study. Each printed circuit board was hand processed by removing any foam or wires before shredding with a plastic shredder. The shredded printed circuit boards were discharged directly into the receptacle pan where grab sampling was performed to obtain the feed samples for the reaction. Due to the highly uniform particle sizes of the shredded feed material, stratification of the feed is minimal Each test used a consistent quantity of feed (20 g samples) which were in close agreement in their sieve analysis. In addition, the feed was sieve-analyzed prior to treatment and after separation into density fractions. This was done so that the effect of particle size to liberation could be observed; these results are not contained within this particular analysis.

The response of yield and grade was found for varying the variables of agitation and percent active reagent in the diluent. The samples were agitated using a Teflon impeller attached on an overhead mixer. The mixer's rotational speed was measured using a tachometer and held constant through each test by manually checking. It was found that once the operating temperature of 150° C. was reached, there was little to no drift in the rotational speed of the mixer. All tests were conducted over the course of 24 hours. Percent solids of the reaction were also held constant at 30% through all runs. The active reagent is a small molecule which is solid at room temperature but is a liquid at the operating temperature. The small molecule is highly effective in delaminating printed circuit boards through the bisphenol-A diglycidyl epoxy layer as determined by computational predictions made using COSMO-RS theory and confirmed using small scale experimental tests. The diluent for this reaction was an inert substance which, on its own, does not cause delamination within the board. The diluent was chosen for its high boiling point and temperature stability even with high concentrations of active reagent dissolved at the operating temperature.

### Determination of Yield

The determination of the yield of the process was performed almost identically to the density separation performed in the preliminary tests. However, because complete liberation of the heavy fraction is not achieved, due to pieces of metal with still attached polymer also being heavy enough to separate in density separation, the grade as well as the total yield was determined. To perform analysis, the treated boards are separated using float-sink analysis in a solution of lithium meta tungstate. This process creates several fractions of boards based on density. The concentrate fraction is the densest fraction and contains most of the delaminated copper foil and ceramic components. Glass fibers and polymer solder masks report to the lighter density fractions provided they are completely liberated from the metal phase. However, metallic particles will still report to the concentrate even if the particle is not completely liberated but the entire particle's composite density is greater than that of the tungstate solution. The total mass percent of the fraction in the concentrate is referred to as the yield. However, the grade of the concentrate can vary based on the degree of liberation which occurs.

### Determination of Grade

In order to determine the extent of liberation of the particles, grade is also determined. The test is performed by finding the percent of the concentrate which is dissolvable in aqua regia. Copper, the primary component of the metallic fraction, is dissolvable in aqua regia. In addition, gold films which coat some of the copper foil are also dissolvable. Aqua regia will also dissolve tin, a major component of solder. Silver will not dissolve. Because,a majority of the concentrate is copper, tertiary metals such as silver are not of great concern. Furthermore, most plastics and glass have resistance to aqua regia and thus will not be significantly dissolved by the acid treatment. Additional doses of concentrated nitric acid were added throughout the process which may have allowed some silver to be dissolved. Ostensibly, the acid digestion removes most metals from the boards while leaving behind the glass fibers and polymers which is the goal of the delamination process. Thus, the direct relationship between the grade and the amount of delamination can be determined for the process.

From these facts, even if complete delamination occurs, the grade of the concentrate will not necessarily be near 100% due to the presence of surface components within each board. These surface components manifest as small ceramic resistors and capacitors and typically comprise roughly 10% of the total mass of the concentrate. These components could be removed through depopulation of the boards prior to delamination. Even the most liberated concentrate in this disclosure and testing was only roughly 85% dissolvable.

Two responses were used in the screening, the percent yield and the percent grade.

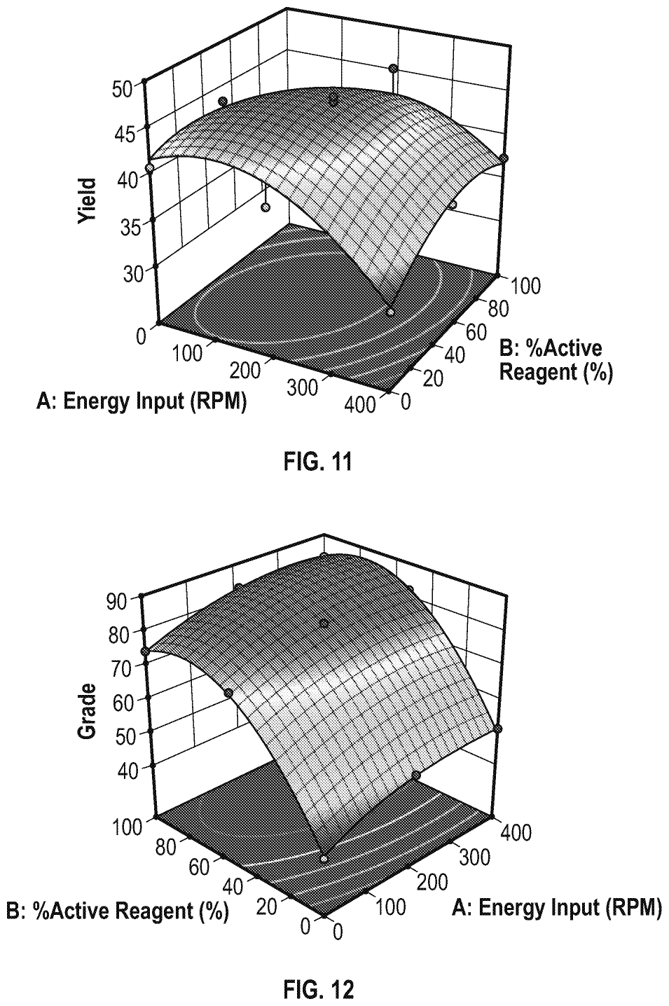

FIGS. 11 and 12 show the generated response surfaces for yield and grade for the process, respectively. It can be seen in FIG. 11 that the yield is quadratically controlled from both an energy input and % active reagent perspective. The high variability in the graph is likely due to the large variance in feed composition in terms of the number of particles that could possibly report to the con. Given the nature of the heavy media separation, as discussed above, certain particles have enough bulk density to report to the con without liberation. There is a second group of particles which can report to the con if there is sufficient liberation, but not complete liberation. This second group makes up most of the particles which contain enough metal that they could report to the con. However, as liberation continues, more material is liberated from this first and second group which decreases the total mass of the con. Increasing active reagent and the energy input facilitates this process. There is the question of the AB term in the yield model and what the significance of that term is. Active reagent and energy input are independent processes; however, there is a possibility that they could work synergistically in delamination of particles, which contain feed-throughs. These feed-throughs act like rivets and prevent delamination in runs without agitation. Agitation appears to either damage the feed-through allowing the particle to split open or provides enough turbulence in the liquid so that fiber and polymer mass, which is contained within the boards, can be mechanically removed from the board facilitating liberation. Regardless of the exact mechanism, agitation does seem to improve the quality of the final particles (grade) as seen in FIG. 12.

Examining FIG. 12 more closely, it can be seen that active reagent and grade appear to be quadratically related. Instead of an expected sigmoidal response to liberation, the grade likely plateaus around this region, with minor pieces of organic material being removed through higher agitation. The remaining particles after dissolution of tests with high active reagent and high energy are not organic but instead simply ceramic surface components which are resistant to acid attack. However, the steep decline in the grade at reagents below 50% shows that this process rate might kinetically decrease as the amount of active reagent decreases.

Polymer swelling occurs in different stages starting with penetration of the molecule into the structure. In this case, the polymer is the solvent and the molecule is the solute. As the number of solute molecules increases, volumetric effects begin to take place. This happens because the Gibbs free energy of mixing for the system is negative and strongly favors more solute molecules dissolving into the polymer matrix. This stage is known as swelling. Eventually, this process is further exasperated as the polymers become sterically untangled and the polymer becomes a gel. From this phase, the individual strands of polymers can be brought into solution. Due to the high degree of cross-linking in epoxies, it is unlikely that this true dissolution stage is reached, at least in the time frame of these screening tests. As the concentration of the active reagent decreases, the osmotic pressure, the force that the molecules needs to penetrate the polymer matrix, decreases.

While the grade, as well as the con, seem to have a large operating area which is beneficial since it allows the process to be conducted in a variety of conditions, the non-metallic tails product seemed to be very sensitive to the operating conditions. The tails product consisted of various morphologies of fiber glass to semi-impregnated composite boards. In Appendix A, there is an image of several tailing fractions from the tests. Depending on the desired morphology, the process can be tailored to achieve the correct non-metallic product.

### Mass Gain and Swelling Tests (NMP/Resorcinol)

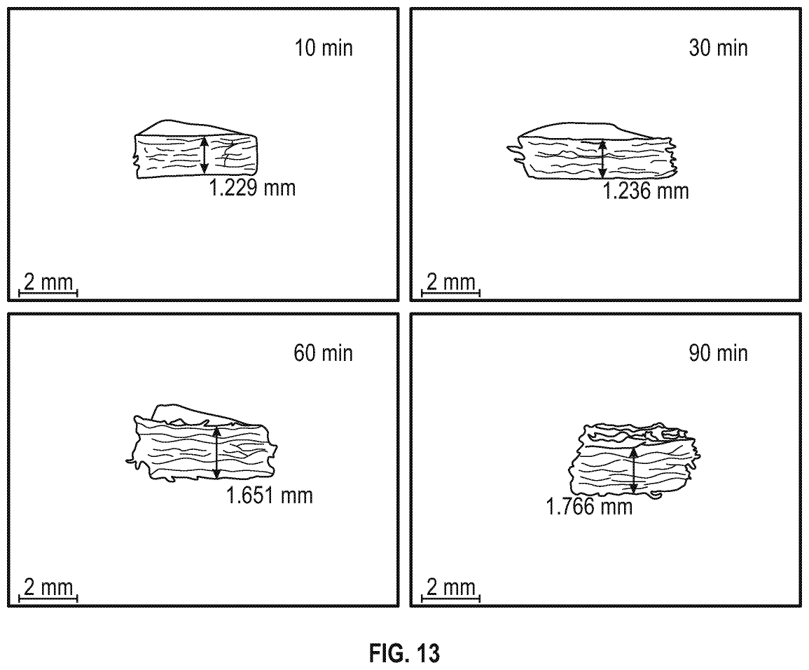

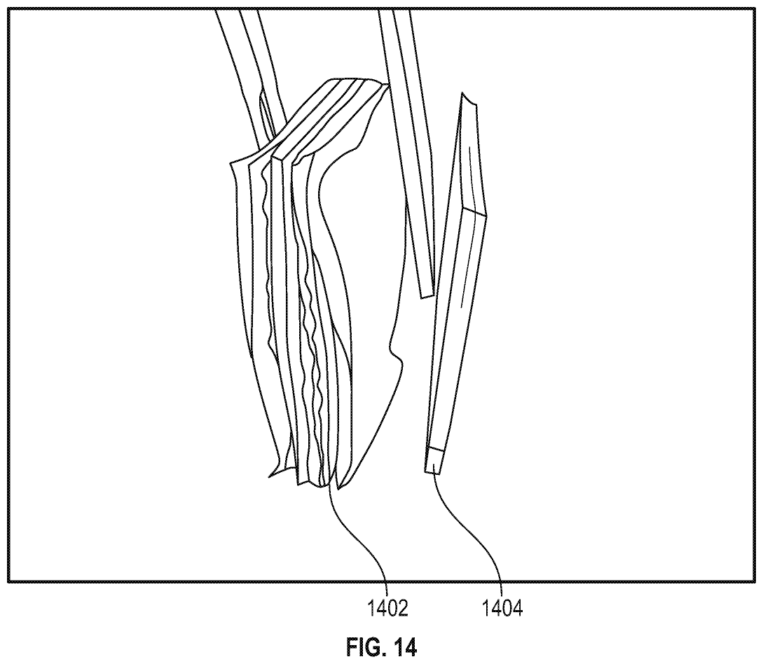

A solution of NMP and resorcinol (9:1 ratio by mass) was made and heated to 112° C. Samples of RAM board were cut from the parent board and weighed on an analytical balance. The initial widths of the board were measured using calipers and the boards were then placed in the solution and samples were taken out at 10, 30, 60, and 90 minutes. The boards were rinsed with water and then methanol and were subsequently allowed to air dry overnight to remove any methanol but as to not drive out any solvent within the boards via heat. Subsequently, the boards were weighted, and the widths were measured under a stereoscope as shown in FIG. 13. A partially delaminated piece of PCB 1402 is shown next to a fresh PCB piece 1404 in FIG. 14.

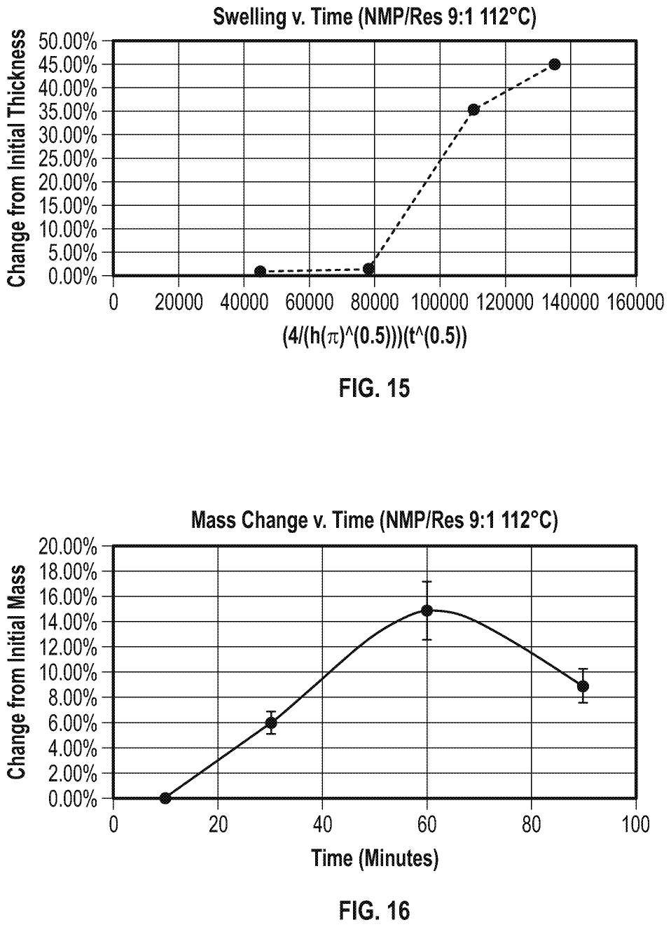

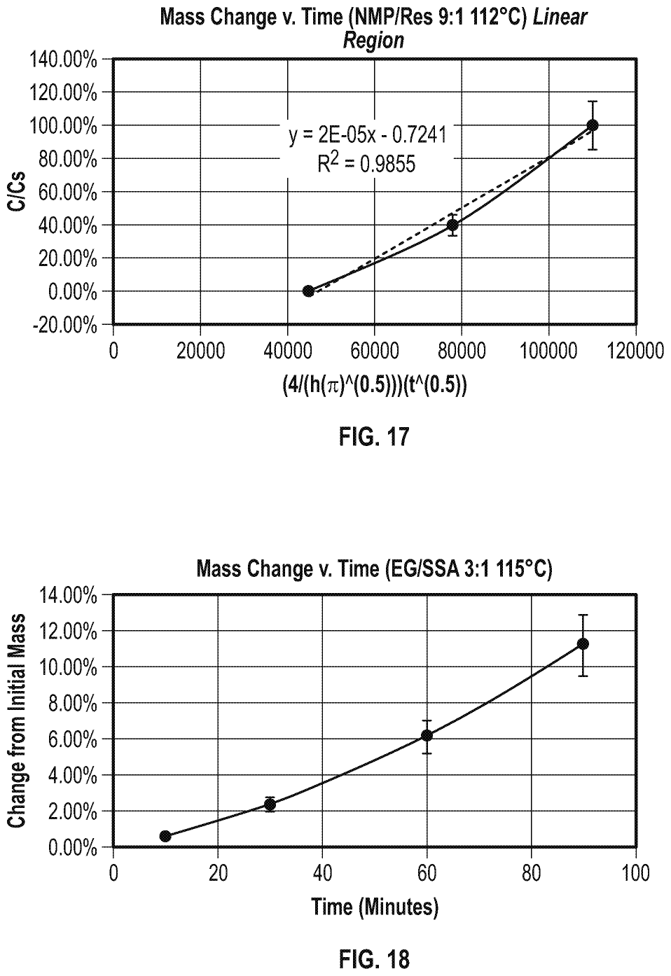

The increase in the widths (swelling) as well as the mass increase is plotted below in FIGS. 15 and 16, respectively. Mass increase was averaged over three separate tests, error bars representing one standard deviation (which is at most approximately 13% of the mean) are included to show the deviation of the sample's mass change. Taking the linear region of the mass change graph and plotting the square root of time (t) and the reciprocal of the sample thickness (h) the graph shown in FIG. 17 can be created. The square of the slope of this graph is the apparent diffusion coefficient which was calculated to be 5.29*10⁻¹² (m²/s).

### Mass Gain and Swelling Tests (Ethylene Glycol/Salicylic Acid)

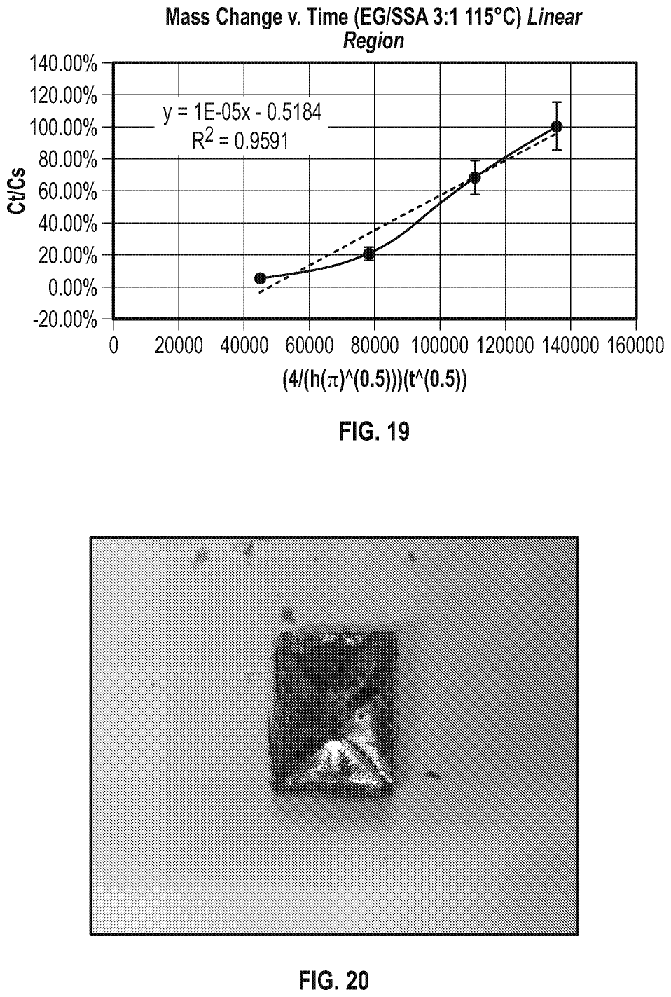

An identical procedure was carried out for obtaining the mass gain plot for ethylene glycol and salicylic acid (3:1 by mass) reagent mix. This data is summarized in FIGS. 18 and 19. Due to equipment limitations the temperature was kept at 115° C. vs the original 113° C. However, this small difference should not change the apparent diffusion coefficient by much. In addition, as can be seen in FIG. 18, there was no drop off in mass and it is unclear if saturation was reached.

It is in fact unclear if saturation was reached in either test. The mass loss was taken to be the point where swelling stopped, and release was beginning. However, from SEM data shown in part below, polymer release may not be a large factor in the mass loss. Instead, the mass loss may be from either fluctuation in the material itself (although unlikely since replicate samples all indicated similar values), or caused by some other type of material loss. Precautions were taken to ensure even parts of the treated board which fell off in the process were captured, but small particles released would be impossible to account for. Even if the 90 minute value is not true saturation, a rough idea of the apparent diffusion coefficient for this region of the curve can still be found.

Three samples at each time were taken and the error bars represent one standard deviation in the mass change which corresponds to approximately 11% of the mean at most (similar to the prior test). No swelling measurements were taken for the ethylene glycol/salicylic acid tests. The calculated apparent diffusion constant was 1.18*10⁻¹² (m²/s).

From the data presented there are several differences between the NMP/resorcinol and ethylene glycol/salicylic acid solvent systems. From the data, the NMP/resorcinol system appears to have faster kinetics, reaching a “saturation” faster than the ethylene glycol/salicylic acid system which was still increasing in mass after the 90-minute test for all the replicate samples. To complement this assessment are the two apparent diffusion coefficients of 5.29*10⁻¹² and 1.18*10⁻¹² (m²/s) for NMP/resorcinol and ethylene glycol/salicylic acid systems, respectively. Finally, the mass gain is in good agreement with thermogravimetric analysis data supplied in future section; thus, the accuracy of the data appears to be in check.

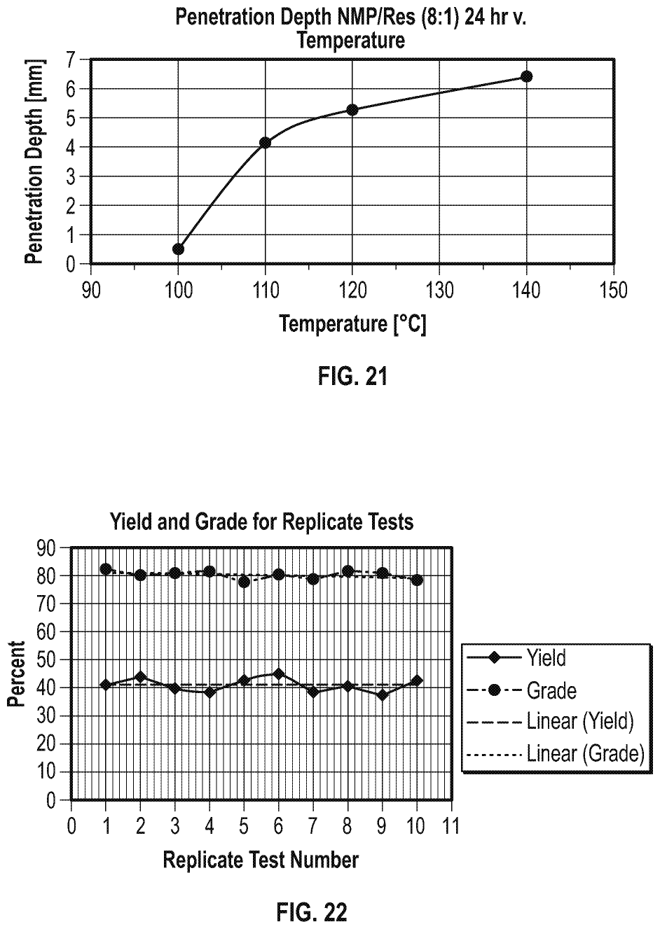

Upon exposure to NMP/resorcinol (8:1) for a duration that did not allow for complete delamination, the edges of the board begin to peel up as seen in FIG. 20. This peeling works its way into the board as a function of both time and temperature. FIG. 21 shows the average penetration distance in millimeters as it relates to temperature. Penetration distance appears to be directly related to temperature. At 24 hours, the penetration depth could not be determined for samples reacted at a temperature greater than 140° C. since complete penetration would cause complete delamination. Penetration depth decreases rapidly below 110° C. to almost nothing. This graph shows that delamination is highly temperature dependent and will not occur to any significant extent below a certain threshold temperature. Above the temperature, increasing the temperature can lead to some marginal gains in penetration rate. For the circuit boards run in this study, this temperature appears to be somewhere just below 110° C. This graph agrees with FIG. 12, which shows a similar cut-off for an entirely different reagent set and different circuit boards.

Scanning electron microscope (SEM) analysis indicates that there are some mechanistic factors which can be deduced. First, the solvent system does not remove all the epoxy contained in the boards. The solvent system cannot, at the times and temperatures used in the diffusion tests, cause complete evisceration of the polymer system. It is likely that a small quaintly of epoxy is able to be removed and this removal occurs in regions that have been delaminated or have been in intimate contact with the solvent system. It is apparent that the adhesion between the epoxy layer and the copper foil weakens with exposure with the solvent system.

The solvent systems of the present disclosure lend themselves to repeated use for several reasons, including that the amount of polymer dissolved into the solvent system is low. The solvent systems of the present disclosure are therefore reusable. By reusing solutions multiple times, the amount of waste from the methods disclosed herein is greatly reduced and the process becomes more economically viable. Longevity tests conducted over the course of several weeks with no cleaning or altering of the initial solution besides light filtering of the delaminated product from the solution show no significant detriment to yield and grade of the con. The resulting product was tested for yield of con as well as the grade of the con, with results shown in FIG. 22. In addition, further stress testing was done by limiting the nitrogen blanket with the goal of allowing the system to be slightly oxygenated to mimic oxygen aging.

### Particle Size and Relation of Practical Diffusion to Liberation

A study of the effect of particle size was also conducted to determine if there was a correlation between the overall size of the particle and what density class the particle would report to after treatment. To prepare this test a 60 g sample of shredded hard-drive PCB feed was used as feed and was added into to a 500 mL reaction kettle with condenser column, and gas diffuser. A 10:1 by mass solution of NMP and resorcinol was used as a solvent. Temperature was held at 120° C. with a nitrogen blanket in order to slow the reaction kinetics and to, hopefully, achieve greater resolution. In addition, the sample was reacted for 8 hours instead of the customary 24 hours for the same purpose. No agitation was used during the test; however, during the initial filtering of the solvent, the treated boards were vigorously stirred by hand to separate any “loose” boards. Agitation during the reaction was avoided in an attempt to keep the non-metallic fraction intact with minimal damage in the form of felting. If felting had occurred, the particle size analysis of the tails would be inconclusive since felting causes the size of the particles to change. When there is little to no agitation, a fairly clean non-metallic tail can be achieved.

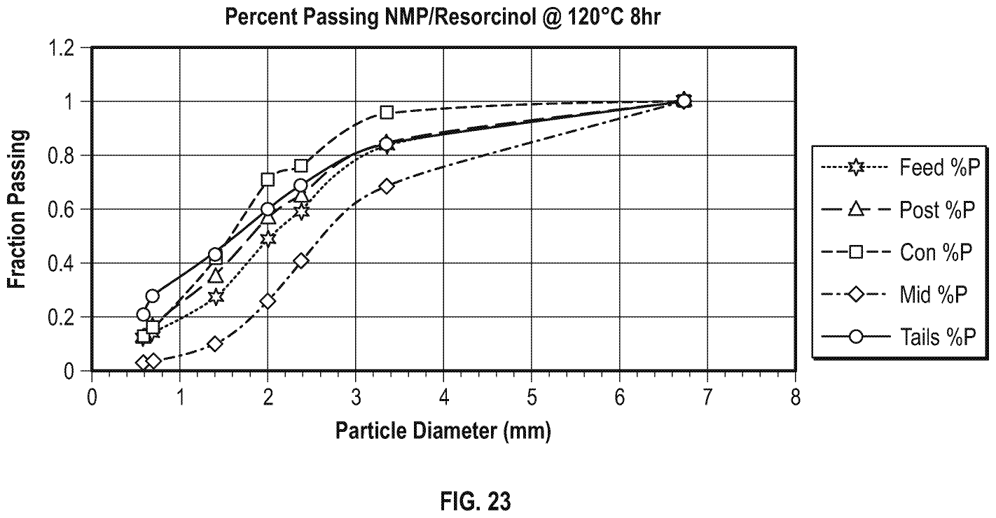

The product was washed with methanol in a Soxhlet extractor overnight and dried in an oven before sieve analysis. The sieve sizes were recombined and then separated using LMT. The separation used the same liquid densities used in the ethylene glycol/salicylic acid study. The lights, mids, and heavys, referred to as the tails, mids, and con, respectively, then underwent their own separate sieve analysis. The results of the total sieve tests are compiled and plotted below in FIG. 23.

The feed for this test was representative of the prior test, and yielded a good distribution of con, mids, and tails. Exclusively looking at the P80 line, there is certainly a difference between the con, mids, and tails. With cons having a slightly smaller P80 than the feed and mids, and with mids having a much larger P80 than the feed. This shows that mids, which are generally non-liberated particles which have a large amount of metallic content (and thus would be prime targets for delamination) are generally larger particles than liberated particles which report to the con and the tails. When combined with the diffusion studies, this shows that smaller grind sizes will liberate to a higher degree and will likely liberate faster than larger particles. While the process can liberate very large particles, the larger the particle the more time the process takes. Thus, in order to decrease the amount of time that the particles are exposed to the solvent, the particle size should be decreased. Decreasing the exposure time is important because the longer the polymer is exposed to the solvent, the more mass the particle will gain. This mass is almost certainly from the intake of the solvent into the polymer matrix. This mass appears to go as high as 10% of the total mass of the processed board. However, if the exposure time is decreased, the mass uptake will be lowered. It is important to note that these numbers, like so much of the data in this thesis, is simply based on the circuit boards which were available for study. Depending on the exact chemical makeup of the board, these numbers may change.

### Conclusions

In general, reagents play an important role in achieving delamination of PCBs. The effectiveness of a reagent is primarily determined by its interaction between the reagent and the polymer and the reagent and the rest of the system. The rest of the system will be the reagent-reagent self-interaction. When a third chemical species is added (such as a diluent) the reagent-reagent self-interaction is balanced by the reagent-diluent interaction. By virtue of being soluble, the reagent-diluent interaction is made to be larger than the reagent-reagent interaction, or else the reagent would not be soluble in the diluent. Further, if the reagent-diluent interaction overpowers the reagent-polymer interaction, swelling will all but cease. When a reagent such as resorcinol (which has a much lower solubility in NMP than salicylic acid in ethylene glycol) is used in conjunction with NMP, a more aggressive swell can occur. Furthermore, NMP (unlike ethylene glycol) is a mild swelling agent itself and will help facilitate solvent penetration.

Another factor in PCB delamination is temperature. Most boards will not delaminate below a temperature of about 110° C. This happens to be the same region that many bisphenol-A epoxies undergo their glass-transition temperature. The diffusion constants for NMP/resorcinol as well as ethylene glycol/salicylic acid solvent systems were found for the minimum operating temperature of approximately 115° C. The NMP/resorcinol solvent system has a much larger effective diffusion constant, which explains its perceived faster kinetics. In addition, the linear penetration of the delamination process was tracked for NMP/resorcinol solvent system at varying temperatures. It was found that increasing the temperature past a certain “activation” temperature was the only way to achieve significant delamination. Increasing it past the “activation” lead to increasing delamination rates. Therefore, increased temperature increases delamination, within limits of breakdown temperatures and limits on pressure at which delamination is performed.

Another factor is agitation. It was found that feedthroughs (through vias and connectors, for example) can act as mechanical binders preventing complete liberation (despite complete delamination occurring). Agitation aides in achieving a high grade of the product. The exact amount of agitation will depend on the reactor as well as operating conditions. It appears that agitation helps mechanically dislodge “stuck” material within the boards. Specifically, fiberglass strands sandwiched between two layers held together by a feedthrough. Agitation does not seem to break any feedthroughs. It appears that stirred tank reactors are sufficient in achieving the required degree of turbulence to fully liberate the boards.

Another factor that appears to affect grade was surface components (especially in larger size fractions). Surface components follow the con with density separation and lower the grade. It was found that by hand picking out the surface components, the grade (in the larger size fractions) could be increased by more than 11%. Mechanical removal of surface components can positively impact the grade if the greatest concentration of metals possible is the goal. The delamination process, (for the shredded PCBs used in this study at least) plateaus out around 80% grade. These numbers could be slightly increased by using a higher density medium for separation or a different process altogether. The plateau from a practical perspective allows for an amount of leeway in the exact operating conditions used for delamination.

The use of multiple solvents/diluents over only one increases the rate of delamination as well as the magnitude of PCB swelling, and thus is superior to single solvent use systems. COSMO-RS predicts favorable reagents for the processes disclosed herein, which use unconventional solvents which are much more effective in delaminating PCBs than the single solvent systems used previously.

Although the present disclosure has been described with reference to preferred embodiments, workers skilled in the art will recognize that changes may be made in form and detail without departing from the spirit and scope of the disclosure.

What is claimed is:

1. A method of delamination of a printed circuit board, comprising:
comminuting the printed circuit board;
soaking the comminuted PCB in a solvent system comprising at least two solvents;
separating solids; and
electrostatically separating different specific solids from the separated solids.

2. The method of claim 1, wherein soaking in a solvent system comprises soaking in a system of reagents comprising two swelling agents.

3. The method of claim 2, wherein the at least two swelling agents comprise n-methyl-2-pyrrolidone (NMP) and resorcinol.

4. The method of claim 2, wherein the at least two swelling agents comprise ethylene glycol and salicylic acid.

5. The method of claim 2, wherein the solvent system further comprises a diluent.

6. The method of claim 1, and further comprising agitating the solvent system.

7. The method of claim 1, wherein soaking in the solvent system further comprises soaking at a temperature of about 110° C. to about 210° C.

8. The method of claim 1, wherein electrostatically separating is preceded by rinsing and drying.

9. The method of claim 1, wherein the at least two solvents comprise solvents having a combined high interaction parameter between the solvent system and polymers of the PCB.

10. The method of claim 1, where separating solids comprises density separation p 52.

11. The method of claim 1, wherein the solvents are chosen based on a predicted normalized interaction with polymers of the PCBs.

12. A method of delaminating a printed circuit board (PCB), comprising:
shredding the PCB;
swelling the shredded PCB with a swelling agent bath comprising at least two swelling agents; and
agitating to assist in delaminating the swelled shredded PCB.

13. The method of claim 12, and further comprising providing a diluent to the swelling agent bath.

14. The method of claim 13, wherein the swelling agents are chosen based on a predicted normalized interaction with polymers of the PCB.

15. The method of claim 12, wherein the at least two swelling agents comprise n-methyl-2-pyrrolidone (NMP) and resorcinol.

16. The method of claim 15, and further comprising providing a diluent to the swelling agent bath.

17. The method of claim 12, and further comprising agitating the swelling agent bath.

18. A method of recovering components of a printed circuit board (PCB), comprising:
shredding the PCB;
delaminating the PCB with a solvent system;
wherein delaminating comprises soaking in the solvent composition bath comprising a swelling agent and a diluent, wherein the swelling agent is a combination of at least two reagents.

19. The method of claim 18, wherein the solvent system is used at a temperature of about 110° C. to about 210° C.

20. The method of claim 18, wherein the solvent system swelling agents comprise n-methyl-2-pyrrolidone (NMP) and resorcinol, in a by mass ratio of NMP to resorcinol of at least 8:1.
